(19) United States
(12) Patent Application Publication
(10) Pub. No.: US 2025/0293480 A1
(43) Pub. Date: Sep. 18, 2025

(54) SEMICONDUCTOR OPTICAL DEVICE AND FABRICATION METHOD

(71) Applicant: Fraunhofer-Gesellschaft zur Förderung der angewandten Forschung e.V., München (DE)

(72) Inventors: Martin MÖHRLE, Berlin (DE); Michael THEURER, Berlin (DE); Gayatri VASUDEVAN RAJESWARI, Berlin (DE)

(21) Appl. No.: 18/606,141

(22) Filed: Mar. 15, 2024

(51) Int. Cl. H01S 5/12; H01S 5/227; H01S 5/343

(52) U.S. Cl. CPC H01S 5/12; H01S 5/2275; H01S 5/343

(57) ABSTRACT

A higher modulation speed is achieved by designing a semiconductor optical device in such a manner that a ridge semiconductor structure which, along with a semiconductor substrate and an active layer formed between the ridge semiconductor structure and the semiconductor substrate, forms a diode of the semiconductor optical device, widens from the active layer towards a face of the ridge semiconductor structure facing away from the active layer, and if the active layer is laterally confined to be within a projection of the face onto the active layer in a direction perpendicular onto the semiconductor substrate. In particular, by this means, it is possible to structure the active layer in a self-aligned manner by using the face of the ridge semiconductor structure facing away from the active layer as a mask in dry etching, and thereby structuring, the active layer.

### BACKGROUND OF THE INVENTION

The present application relates to semiconductor optical devices and their fabrication such as light-emitting devices such as, but not exclusively, DFB (distributed feedback) lasers.

For optical data transmission in telecom systems, within data centres or within high performance computing systems, high speed transmitter components are needed. High speed DFB lasers, in particular in the o-band wavelength range, are key components for these applications.

Within the last ten years, significant R&D effort has been carried out in order to increase the modulation speed of the DFB lasers by optimizing the InGaAlAs MQW (multiple quantum well) active layer and the DFB grating regarding high relaxation frequency and in addition to that by reducing series resistance and parasitic capacitance of the lasers. In this way, DFB lasers with a frequency bandwidth up to 30 GHz at room temperature operation were achieved.

However, quite recently there were some new developments regarding DFB lasers with a frequency bandwidth of 40 GHz or even higher.

One approach to achieve this is the use of so-called membrane lasers with lateral current injection. With such devices, modulation bandwidths greater than 40 GHZ and, using the photon-photon resonance effect, even greater than 100 GHz have been achieved [1.1]. However, such membrane lasers suffer from a very low optical output power <<1nW so that for a lot of applications they cannot be used. The second approach makes use of a method already proposed in 1993 [1.2] to increase the modulation bandwidth by increasing the ratio between the optical confinement factor and the mode field diameter. This was quite difficult to achieve at that time.

However, with further improving InP technology, this proposed method now turns out to be very promising.

The third approach is the utilization of a groove-in-trench waveguide structure [1.3]. After the formation of the ridge, the groove is etched through the active layer comprised of InGaAlAs MQW and passivated through SiO₂. However, such a device can suffer from the oxidation of the Al-containing material due to technological limitations which results in higher threshold current and lower reliability for narrow groove-in-trench devices. A significant increase in modulation bandwidth was not demonstrated using this approach so far.

LUMENTUM published several papers about DFB lasers with >40 GHz modulation bandwidth since 2020 [1.4 and 1-5]: these lasers have an active stripe width <1 μm and a modified BH-laser design to allow for an optimization of the mentioned confinement/mode diameter ratio. On the other hand, a narrow ridge results in a higher series resistance and, thus, limits the modulation bandwidth. However, since the ridge used here is of n type InP, which has a low resistivity, this effect is mitigated.

As to the fabrication of these devices, reference is made to references 1.6 and 1.7.

To reduce the series resistance of narrow ridge waveguide lasers, the use of V-shaped InP ridges was already proposed in 1997 [1.8].

However, there is a need for providing semiconductor optical devices which allow for an even further improvement in modulation speed.

Thus, the object of the present invention is to provide a semiconductor optical device and a method for fabricating same, in which the semiconductor optical device allows for the achievement of a higher modulation speed.

This object is achieved by the subject matter of the independent claims.

### SUMMARY

A basic finding underlying the present invention is that a higher modulation speed may be achieved if a semiconductor optical device is designed in such a manner that a ridge semiconductor structure which, along with a semiconductor substrate and an active layer formed between the ridge semiconductor structure and the semiconductor substrate, forms a diode of the semiconductor optical device, widens from the active layer towards a face of the ridge semiconductor structure facing away from the active layer, and if the active layer is laterally confined to be within a projection of the face onto the active layer in a direction perpendicular onto the semiconductor substrate. In particular, by this means, it is possible to structure the active layer in a self-aligned manner by using the face of the ridge semiconductor structure facing away from the active layer as a mask in dry etching, and thereby structuring, the active layer.

According to an embodiment, of the present application, the active layer is formed in such a manner that its laterally opposite side faces are laterally arranged between opposite sides of the face of the ridge semiconductor structure on the one hand and sides of an interface between the active layer and the ridge semiconductor structure on the other hand. In other words, the active layer might have a width between the width of the face on the one hand and the width of the interface on the other hand. By this measure, the ridge semiconductor structure is in full contact with the active layer, with the active layer still being narrower than the face of the ridge semiconductor structure serving as the mask for defining the active layer.

Additionally, or alternatively, the width of the active layer transfers to a longitudinal axis of the ridge semiconductor structure may be less than 1 μm.

According to an embodiment, the ridge semiconductor structure has a trapezoidal cross-section. The ratio of the width of the active layer to a width of the face of the ridge semiconductor structure may, for instance, be larger than 7/5. That is, while the active layer is very confined, the light propagation in the ridge is efficient due to the enlarged width of the ridge semiconductor structure.

According to an embodiment, the semiconductor substrate comprises a protrusion onto which the active layer is positioned, and whose lateral extension coincides with the active layer. In other words, the active layer may be formed on a protrusion of the semiconductor substrate so that its lateral opposite side faces coincide with laterally opposite side faces of the protrusion. By this measure, the light is effectively laterally confined to the active layer. A protective layer may cover the laterally opposite side faces of the active layer. This protective layer may further cover portions of a face of the semiconductor substrate, which laterally surrounds the active layer. This protective layer is, according to an embodiment, thin, such as having a thickness smaller than 100 nm or even smaller than 50 nm, or the protective layer is thinner than compared to the height of the protrusion or thinner than the active layer. By this measure, the optically effective width of the active layer may be kept small, with the resulting optical confinement enabling an increase of modulation speed.

In accordance with an embodiment, additionally or alternatively, the material of the ridge semiconductor structure and the semiconductor substrate is indium phosphide (InP). According to an embodiment, additionally or alternatively, the material of the ridge semiconductor structure is of P-type (e.g., p-InP). It is also feasible that the material of the ridge semiconductor structure may be of N-type (e.g., n-InP). Furthermore, the material of the ridge semiconductor structure and the semiconductor substrate may even be GaAs AlGaAs, InGaAsP, InGaAsSb or InAlGaAs.

In producing the semiconductor optical device, the face of the ridge semiconductor structure may be used as a mask in dry etching the active layer so that the active layer becomes laterally arranged within the projection of the face of the ridge semiconductor structure onto the active layer in the direction perpendicularly onto the semiconductor substrate.

In the following description, embodiments are discussed in detail, however, it should be appreciated that the embodiments provide many applicable concepts that can be embodied in a wide variety of the field of semiconductor optical devices. The specific embodiments discussed are merely illustrative of specific ways to implement and use the present concept, and do not limit the scope of the embodiments. In the following description of embodiments, the same or similar elements or elements that have the same functionality are provided with the same reference sign or are identified with the same name, and a repeated description of elements provided with the same reference number or being identified with the same name is typically omitted. In the following description, a plurality of details is set forth to provide a more thorough explanation of embodiments of the disclosure.

However, it will be apparent to one skilled in the art that other embodiments may be practiced without these specific details. In other instances, well-known structures and devices are shown in diagram form rather than in detail in order to avoid obscuring examples described herein. In addition, features of the different embodiments described herein may be combined with each other, unless specifically noted otherwise.

### BRIEF DESCRIPTION OF THE DRAWINGS

Embodiments of the present invention will be detailed subsequently referring to the appended drawings, in which:

FIG. 1 shows a schematic 3D sectional view of a semiconductor optical device according to an embodiment;

FIG. 2a-j shows sectional views of a semiconductor optical device at different states reached during a fabrication method for the semiconductor optical device, here embodied as a DFB laser;

FIG. 3 shows a schematic longitudinal sectional view of a variation of the semiconductor optical device of FIG. 1, here as a DFB laser with a diffraction grating; and

FIG. 4 shows a graph indicative of the dependency of the relaxation frequency increase of a DFB laser on the active layer's width.

### DETAILED DESCRIPTION OF THE INVENTION

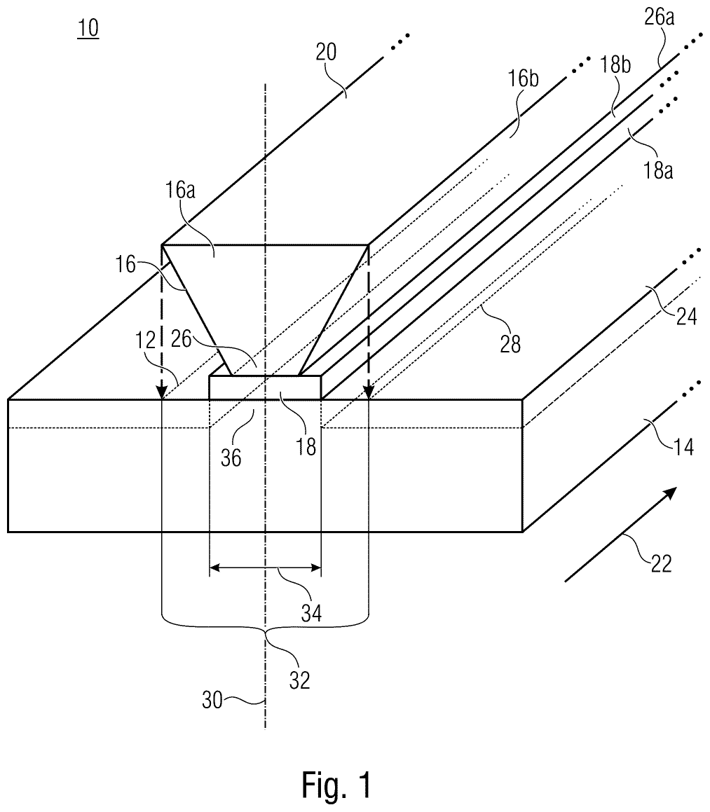

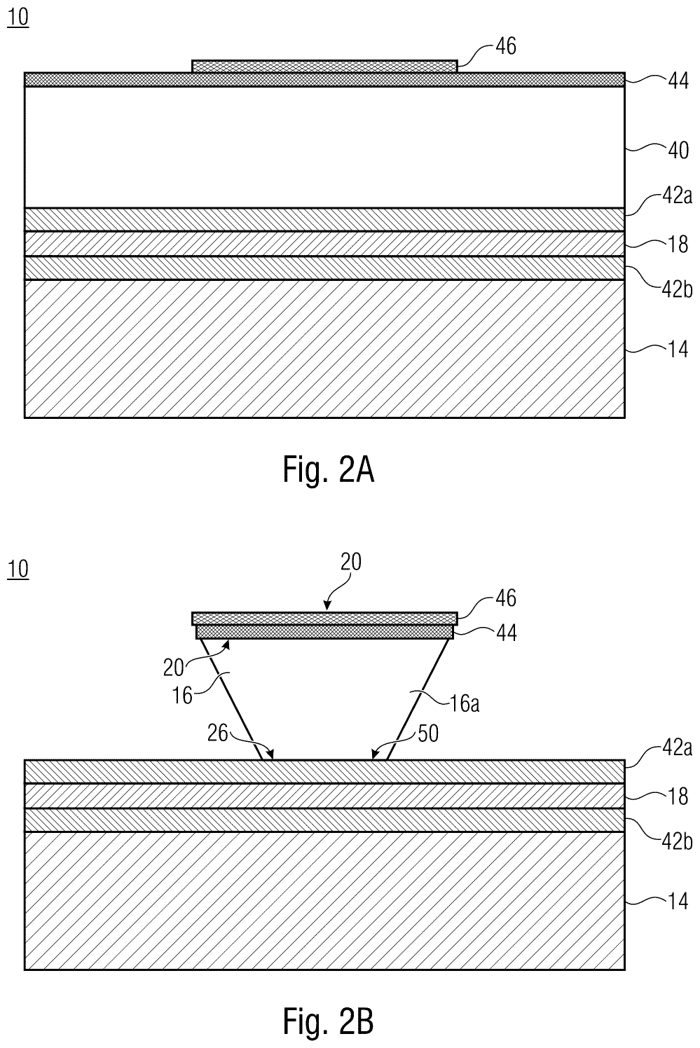

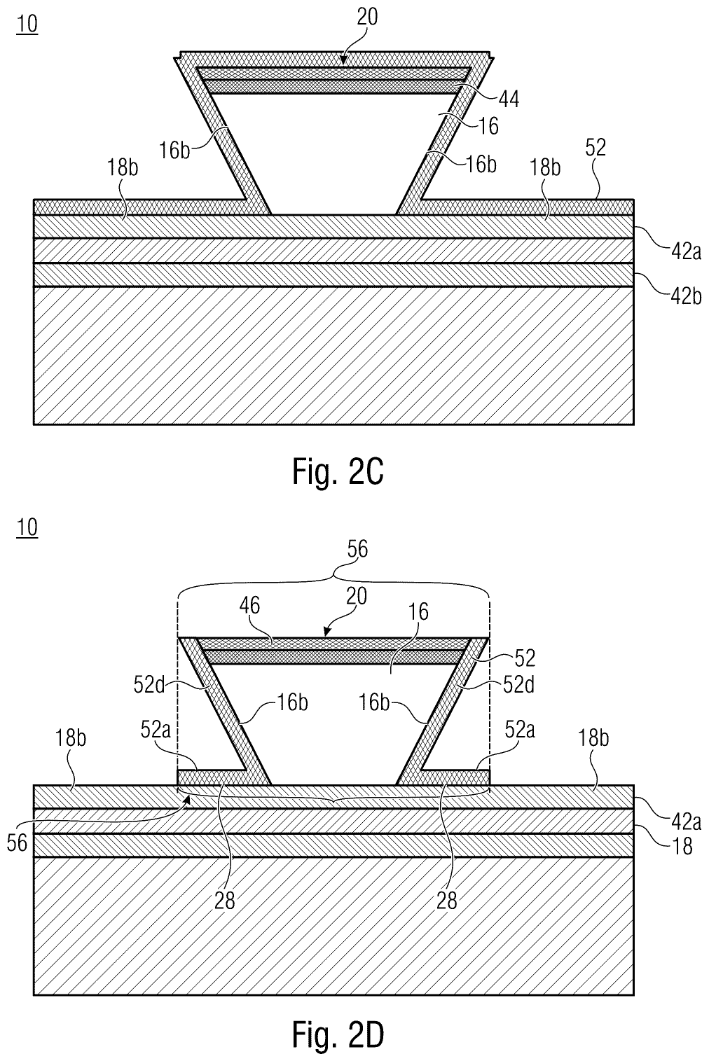

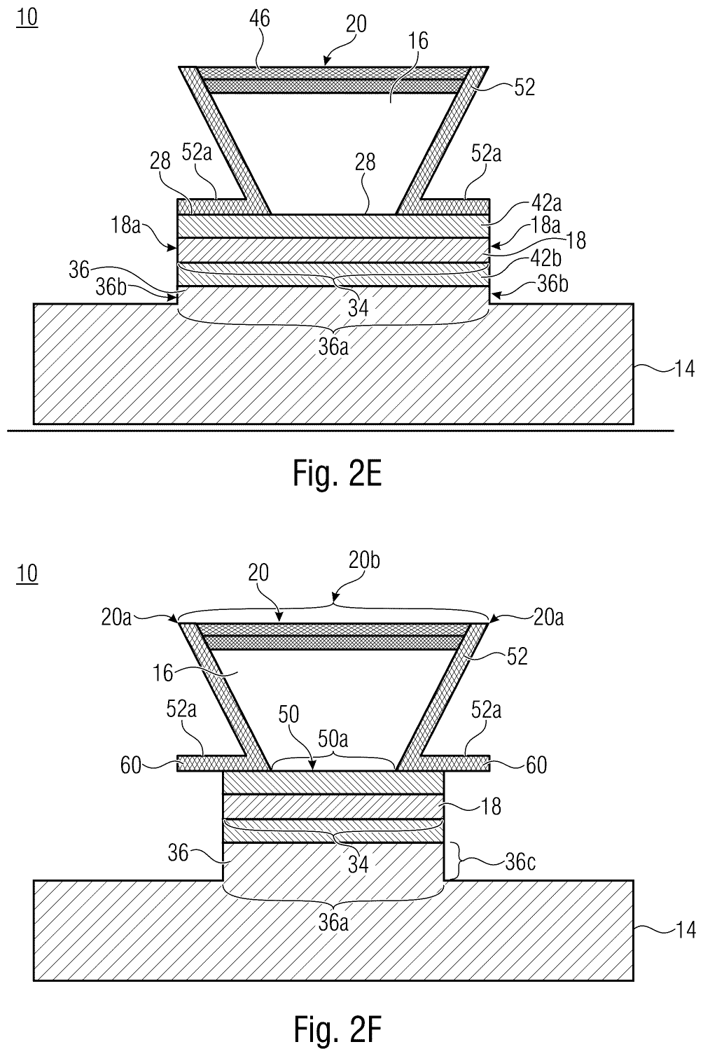

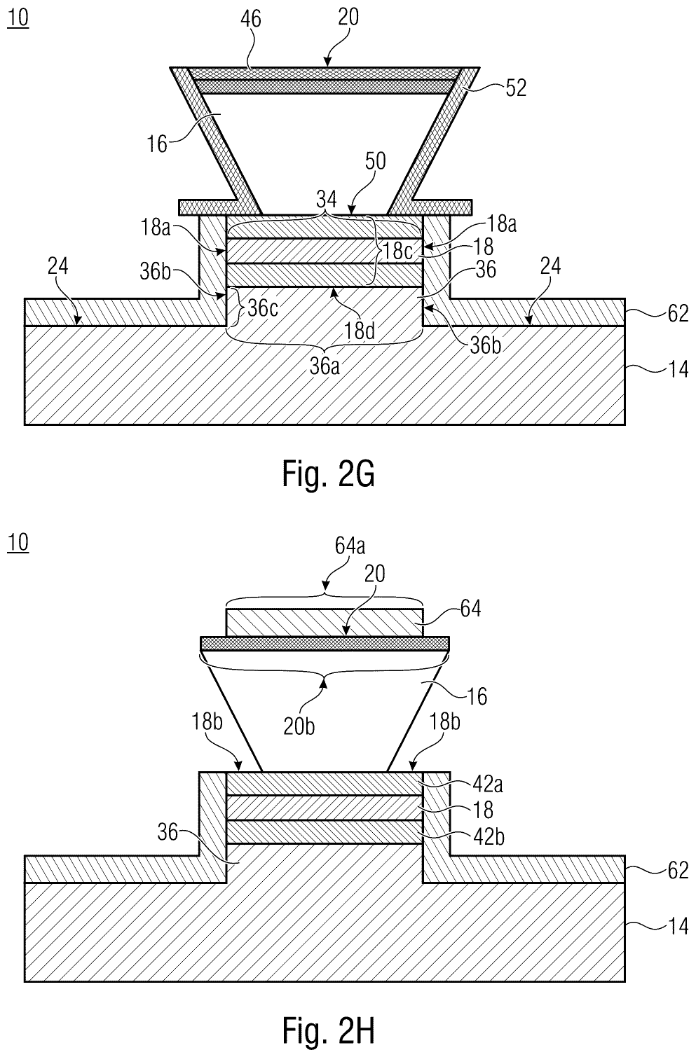

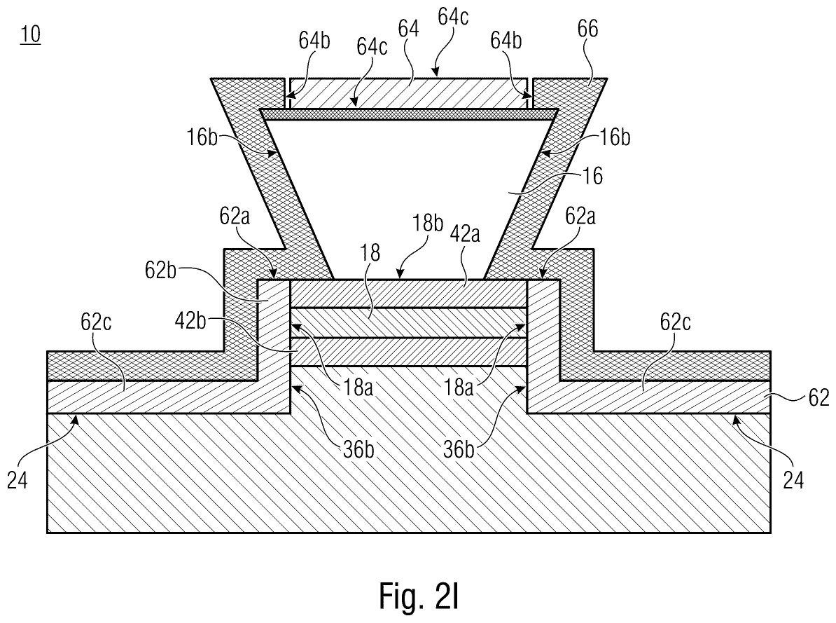

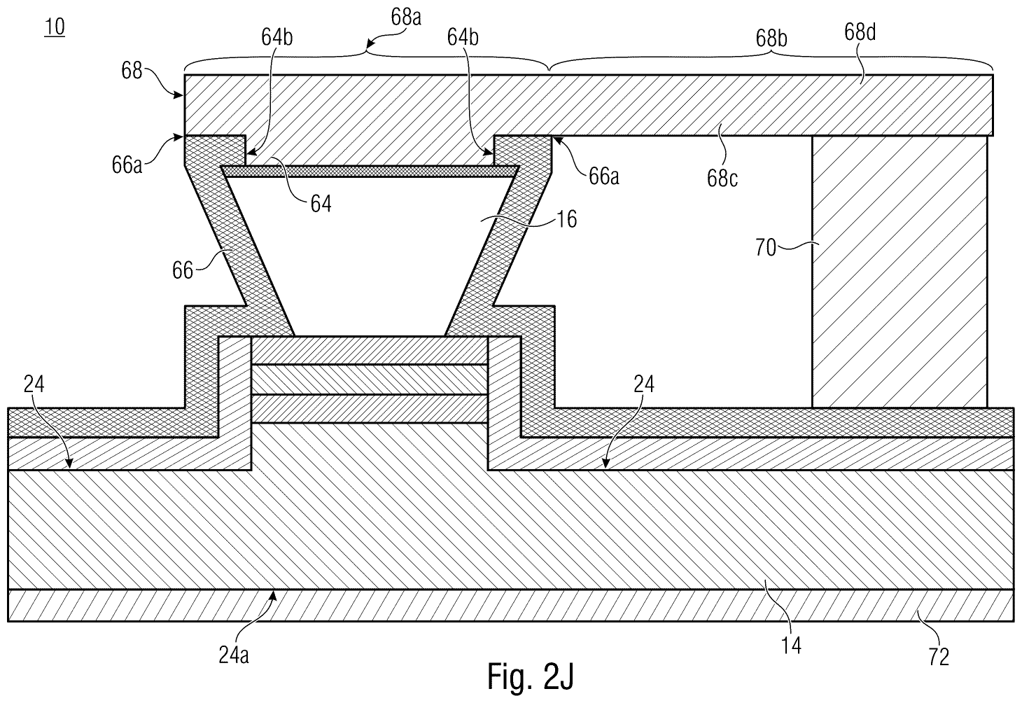

A semiconductor optical device, in accordance with an embodiment, is now described with respect to FIG. 1. The semiconductor optical device 10 of FIG. 1 comprises a diode 12 formed by a semiconductor substrate 14 of the semiconductor optical device 10, a ridge semiconductor structure 16 and an active layer 18 formed between the semiconductor substrate 14 and the ridge semiconductor structure 16. The semiconductor substrate 14 and the ridge semiconductor structure 16 are of opposite conductivity type and are described in more detail below. With respect to FIG. 2a-2j, it might be that the active layer 18 is itself a layer stack, structured at a certain MQW structure and/or sandwiched between certain waveguide layers.

As shown in FIG. 1, the ridge semiconductor structure 16 has a cross-section perpendicular to the active layer, i.e., perpendicular to its lateral extension and a longitudinal extension of both the ridge semiconductor structure 16 and the active layer, which widens from the active layer 18 towards a face 20 of the ridge semiconductor structure 16 facing away from the active layer 18.

As shown in FIG. 1, the ridge semiconductor structure 16 as well as the active layer 18 both extend longitudinally along a longitudinal axis 22. Thus, the active layer 18 is formed as a stripe on a top face 24 of the semiconductor substrate 14 and the ridge semiconductor structure 16 is formed above the active layer 18 in a manner separated from the semiconductor substrate 14 via the active layer 18. FIG. 1 shows a fraction or a longitudinal portion of the semiconductor optical device 10 along side longitudinal axis 22 where the front face is shown in form of a cross section perpendicular to the longitudinal axis 22. As shown in FIG. 1, the ridge semiconductor structure 16 may have a constant cross section 16a perpendicular to the longitudinal axis 22, but there are, naturally, variations feasible.

In the diode 12, the semiconductor substrate 14 is of a first conductivity type while the ridge semiconductor structure 16 is of a second conductivity type. In embodiments described in more detail below, for example, the ridge semiconductor structure 16 is of the p type, while the semiconductor substrate 14 is of the n type, but this configuration may be switched and even the embodiments described below may be switched in this regard.

As shown in FIG. 1, the cross section 16a of the ridge semiconductor structure 16 widens from the active layer 18, i.e., from the interface 26 where the ridge semiconductor structure 16 abuts the active layer 18, towards face 20, and this widening, as already indicated above, lowers the series resistance and, thus, increases the modulation speed of device 10. In the example of FIG. 1 and the embodiments described further below, the cross section of the ridge semiconductor structure 16 has a trapezoidal shape with overhanging sidewalls 16b connecting the upper face 20 with the interface 26 along side the longitudinal axis 22. However, this V-shape may, naturally, be varied, too. As will become clear from the further description, the increased width of face 20 compared to interface 26, i.e., the width measured laterally and perpendicularly to longitudinal axis 22, enables a self-aligned lateral structuring of the active layer 18 by using the ridge semiconductor structure 16 or, to be more precise, face 20 as a mask in dry etching active layer 18.

As shown in FIG. 1, the active layer 18 has a narrow shape, i.e., is formed as a stripe, with being laterally confined to be within a projection 28 of face 20 onto active layer 18 in a direction perpendicularly onto the semiconductor substrate 14, i.e., confined within the area cast by face 20 when being projected towards the semiconductor substrate 14 along the vertical direction 30 perpendicular to the lateral plane of substrate 14. In even other words, the lateral extension of active layer 18 in a direction perpendicular to longitudinal axis 22 is confined to be within, or as a range within, the lateral extension 32 of the area resulting from projecting face 20 onto face 24 of substrate 14. Due to the narrow width of active layer 18, the modulation bandwidth of device 10 is further increased and the width of active layer 18 may be designed to be small due to the possibility of using face 20 for a self-aligned lateral structuring of active layer 18.

Thus, the semiconductor optical device 10 of FIG. 1 is able to act as a light emitting device. In particular, light is emitted responsive to a voltage signal being applied between ridge semiconductor structure 16 on the one hand and the semiconductor substrate 14 on the other hand and due to the construction described and shown in FIG. 1, the modulation speed in modulating the light thus emitted, may be increased. As will be described in more detail with respect to the embodiments described further below, a contact may be arranged at face 20 and another contact at semiconductor substrate 14 such as the face 24a opposite to face 24. As illustrated in more detail below, the light emitting device, thus formed, may be a diode laser such as a DFB laser or device 10 as shown in FIG. 1 may be part of a DFB laser or some other sort of laser as will be discussed in more detail below. It should be noted, however, that the semiconductor optical device 10 of FIG. 1 could, alternatively, be implemented to act as a light receiving device, i.e., a light sensor, converting modulated light, for instance, into a modulated electrical signal output across diode 12.

Although examples for a possible production/fabrication of the semiconductor optical device 10 of FIG. 1 or more detailed embodiments thereof will be presented in the following, brief statements with respect to such method shall be made with respect to FIG. 1 now. In particular, a possible fabrication method may involve depositing the active layer 18 on top face 24 of semiconductor substrate 14 in an unstructured manner where then forming the structure 16 onto the active layer 18 in the form shown in FIG. 1. In that situation, the active layer 18 does not yet have its stripe form and needs to be laterally structured yet. The structuring is then performed using dry etching and, particularly, by using face 20 of the ridge semiconductor structure 16 as a mask in dry etching the active layer, so that as shown in FIG. 1, the active layer 18 becomes laterally arranged with the projection as already described above. While it could be possible that the dry etching is performed such that the dry etching stops right before semiconductor substrate 14 and its upper face 24, respectively, as described in the embodiments described further below, the dry etching may reach-out into, or precede beyond the active layer 18, respectively, thereby resulting into a removal of semiconductor material of the semiconductor substrate 14 on both sides of the projected area 28, thereby resulting into semiconductor substrate 14 forming a protrusion protruding from upper face 24 towards which semiconductor structure 16 having, on its top, active layer 18. Additionally, or alternatively, and as further described in the embodiments described further below, a wet etching, performed subsequent to the dry etching, may be used to further reduce the lateral width 34 of active layer 18 so that the laterally opposite facing side faces 18a of active layer 18 get nearer to each other and nearer to the lateral sides 26a of the interface 26, respectively. This wet etching may additionally contribute to, or even form, the just-mentioned removal of semiconductor material of the semiconductor substrate 14 at its upper face 24 so as to increase the height of, or define the just-mentioned protrusion of the semiconductor substrate 14 having the active layer 18 on its upper end.

The protrusion is illustrated in FIG. 1 by using dashed lines and using reference sign 36. It may have, as shown in FIG. 1, a lateral width or lateral extension perpendicular to the longitudinal axis 22 which coincides with the active layer 18. In other words, the active layer 18 may completely cover the side of the protrusion 36 facing towards the ridge semiconductor structure 16 due to the protrusion being formed concurrently with the lateral structuring of the active layer 18 in the dry etching and/or wet etching, respectively.

As can also be seen in FIG. 1, and as it will also be described in the following, the side faces 18a of active layer 18, and, if present, the protrusion 36 of semiconductor substrate 14, may be left unembedded, i.e., no semiconductor material might surround the side faces 18a of active layer 18. In accordance with embodiments, for instance, protective layer 62 may be formed so as to protect those faces of active layer 18 neither covered by the ridge semiconductor structure 16 nor the semiconductor substrate 14 such as the side faces 18a and, optionally, portions 18b of the face of the active layer 18 facing ridge semiconductor structure 16, external to interface 26. This protective layer 62 may act as a passivation layer abutting the active layer 18 laterally, i.e., on its side faces, and may be formed thin as will be described in more detail below, thereby leaving the effective width of the active layer 18 small and thereby contributing to the improved modulation bandwidth of device 10. However, the protective layer is optional. For instance, the semiconductor optical device 10 may be dedicated to operate in, or may be housed to operate in, a non-reactive or inert environment such as vacuum. For instance, the semiconductor optical device 10 may be operated in an enclosure such as a vacuum-sealed cavity or a chamber filled with inert gas.

After having described an embodiment of the present application with respect to FIG. 1, the present application proceeds with a description of a semiconductor optical device 10, here embodiment as a DFB laser. In particular, with respect to the following FIG. 2a-2j, the following description described an embodiment of a DFB laser and its fabrication.

wav

In particular, FIGS. 2a-2j show the semiconductor optical device 10 in accordance with this embodiment as a sequence of cross sections of the semiconductor device perpendicular to the longitudinal axis 22 at consecutive stages during the fabrication process.

The description starts at a state shown in FIG. 2a, where, in an unstructured manner, the following elements are formed one upon each other sequentially from bottom to top, namely the semiconductor substrate 14, the active layer 18, a layer 40 yet to be structured to form the ridge semiconductor structure 16, followed by a contact layer 44. As can be seen in FIG. 2a, the active layer 18 may be sandwiched between waveguide layers 42a and 42b separating the active layer 18 from the semiconductor substrate 14 on the one hand and the semiconductor layer 40 on the other hand. Above the contact layer 44, a dielectric layer 46 is formed and laterally structured so as to be positioned at and define the position of the ridge semiconductor structure 16.

The contact layer 44 may be formed of metal, for example.

FIG. 2b shows a state of the manufacture of the semiconductor optical device 10 reached from the state of FIG. 2a by structuring, such as by dry etching, layer 40 using the structured dielectric layer 46 as a mask followed by wet etching, such as chemical selective wet etching, the semiconductor material of layer 40 so that the semiconductor ridge structure 16 manifests itself out of layer 40 with the active layer 18 laterally arranged within a projection of the face 20 of the ridge semiconductor structure 16 onto the active layer 18 in a direction perpendicular onto the semiconductor substrate 14, i.e., in a vertical direction 30 perpendicular to the longitudinal axis 22.

The wet etching thus performed results into the overhanging side walls 16. As shown, a trapezoidal or V-shaped ridge semiconductor structure 16 may result, wherein the top face 20 of the ridge semiconductor structure 16 is wider than the bottom face 50 of the ridge semiconductor structure 16. In other words, the ridge semiconductor structure 16 has a cross section 16a perpendicular to the active layer 18, which widens from the active layer 18 towards the bottom face 50 of the ridge semiconductor structure 16 facing away from the active layer. In even other words, the ridge semiconductor structure 16 narrows from the top face 20 facing away from the active layer 18 towards the bottom face 50 facing towards the active layer. The wet etching removes the semiconductor material of layer down to the waveguide layer 42a except for the ridge semiconductor structure 16 and, thus, uncovers portions 18b of an upper face of this waveguide layer.

As can be seen in FIG. 2b, as a result of the dry etching followed by wet etching, the face 20 of the semiconductor material of the ridge semiconductor structure 16 facing away from the active layer, the contact layer 44 and the dielectric layer 46 formed on top of the ridge semiconductor structure's 16 semiconductor material have the same lateral extension. In other words, in the state of FIG. 2b, the contact layer 44 and the dielectric layer 46 form the upper face 20, the width of which is larger than that of interface 26.

As shown in FIG. 2c, a masking layer 52 may then be deposited onto the surface of the semiconductor optical device 10 in a shape conforming manner, thereby reaching the state in FIG. 2c from state in FIG. 2b. This deposition is performed in a manner so that the masking layer 52 covers the portions 18b of waveguide layer 42a, side faces 16b of the ridge semiconductor structure 16 i.e., the overhanging side walls 16b of the ridge semiconductor structure 16, as well as face 20 of the ridge semiconductor structure, i.e. the upper face of contact layer 44. That is, the said deposition may cover the complete upper surface of the semiconductor optical device 10 of the state depicted in FIG. 2b. In accordance with an embodiment, the masking layer 52 may be made of a dielectric material. In particular, in accordance with an embodiment, the deposition of the masking layer may be performed using a chemical vapor deposition process or a sputtering deposition process.

FIG. 2d depicts a state reached from FIG. 2c by structuring the masking layer 52 of the semiconductor optical device 10 using etching and using the ridge's upper face 20 as a mask. In particular, the etching may be performed using dry etching. The dielectric layer 46 as well as the waveguide layer 42a may act as a etch stop for the dry etching. Due to the anisotropy, the masking layer 52 thus remains on the overhanging side walls 16b of the ridge semiconductor structure 16 and on the projected area 28 within portions 18b of the upper face of waveguide layer 42a. In other words, the masking layer 52 is removed at portions lying on top of the ridge semiconductor structure 16 and portions outside the projected area 28, i.e. outside the projection cast onto the waveguide layer 42a by the lateral extension 56 of face 20.

That is, the etching of the masking layer 52 may be carried out by means of mask-less dry etching in that the overhanging nature of the ridge structure is exploited and its upper face 20 used an inherent mask. In case of using a dielectric material for the masking layer, the etching step may be described as a mask-less dielectric-specific dry etching.

As a result of the steps performed to reach the state of FIG. 2d, the dielectric layer 46 and one or more portions 52a, 52d of the masking layer 52 on the overhanging side walls and the area 28 of portions 18b, respectively, completely cover the ridge structure 16, thereby enabling a structuring of the active layer 18 and the ridge semiconductor structure 16 without any alignment problems in a self-aligned manner, as the ridge structure is protected against the wet etching agent.

In the embodiment described with respect to FIGS. 2a to 2d, the structuring of the active layer 18 is performed by use of dry etching followed by wet etching, but there as also alternatives possible where one of the etching steps is used.

FIG. 2e shows the state during manufacture of device 10 reached upon dry etching applied to the state FIG. 2d. The dry etching is performed using the face 20 of the ridge semiconductor structure 16, as a mask so that the dry etching etches the material of the waveguide layers 42a and 42b and the active layer 18 beyond these layers into portions of the semiconductor substrate 14—in portions outside projective area 28, so that a protrusion 36 of a semiconductor substrate 14 results onto which the active layer 18 is positioned, and whose lateral extension 36a coincides with the lateral extension 34 of the active layer 18. In other words, the dielectric layer 46-along with the masking layer 52-acts as a mask for the dry etching, and performing the dry etching longer than needed to remove layers 42a,b and 18 results into formation of the protrusion 36 of the semiconductor substrate 14 as a result of the dry etching into semiconductor substrate 14. In particular, as a result of the dry etching, the active layer 18, the protrusion 36 of the semiconductor substrate 14, the top face 20 of the ridge semiconductor structure 16 and the area enclosed by the outer sides of the portions 52a of the masking layer 52 abutting the waveguide layer 42a within projective area 28 substantially coincide in lateral extension or width, respectively. In particular, the side faces 18a of the active layer 18 and the side faces 36b of the protrusion 36 of the semiconductor substrate 14 are in alignment, in a vertically spaced configuration parallel to a vertical axis 30, with each other. In other words, they are substantially co-planar.

It is also understandable from FIG. 2e that the lateral width 52a of the bottom face 50 of the ridge semiconductor structure, which interfaces, here via waveguide layer 42a, the active layer 18, may be smaller than or even be equal to the lateral width 34 of the active layer 18.

In principle, the protrusion of the substrate 14 might be interpreted to from a bottom ridge on which the ridge semiconductor ridge 16 is formed, separated by the stack of active layer 18 and waveguide layers 42a,b.

FIG. 2f shows the state of the semiconductor optical device 10 during fabrication reached by wet etching applied to the state in FIG. 2e. The wet etching is performed using the face 20 of the ridge semiconductor structure 16 as a mask so that the wet etching reduces the lateral extension 34 of the active layer 18 and the lateral extension 36a of the protrusion 36 of the semiconductor substrate 14. The masking layer 52 covering the ridge semiconductor structure 16 and the dielectric layer is resistive with respect to the performed wet etching and as a result protects the ridge semiconductor structure 16.

The wet etching is performed so that, relative to a projection of the face 20 of the ridge semiconductor structure 16 onto the active layer 18, the sides 18a of the active layer 18 and the sides 36b of the protrusion 36 of the semiconductor substrate 14 get closer to each other, i.e. their lateral width perpendicular to the longitudinal axis 22 is reduced, and such that they become both arranged between the opposite sides 20a of the top face 20 of the ridge semiconductor structure 16 and the sides 26a of the interface 26 between the active layer 18 and the ridge semiconductor structure 16. In other words, as a result of the wet etching, the lateral extension 34 of the active layer 18 and the lateral extension 36a of the protrusion of the semiconductor substrate 14 are confined within a range, ranging from the lateral width 50a of the bottom face 50 of the ridge semiconductor structure 16 to the lateral width 20b of the top face 20 of the ridge semiconductor structure 16.

As can be seen in FIG. 2f, after the wet etching, the width of the lateral extension 34 of the active layer 18 and the waveguide layers 42a, 42b may be equal to the the width of the lateral extension 36a of the protrusion 36 of the semiconductor substrate 14. However, in case of the etch rate being slightly different between the waveguide layers 42a,b and the active layer 18, their width may slightly differ, too. As can also be seen in FIG. 2f, the laterally extending portions 52a, of the masking layer 52 form, owing to having sustained the wet etching, an overhang 60 on the active layer 18.

That is, the portions 60 of the masking layer 52 extend laterally outwards away from the active layer 18 such that the portions 60 hang over the active layer 18. In even other words, the wet etching results leads to an under etching so that parts 60 of the laterally extended portions 52a of the masking layer 52 are not supported by the active layer 18.

In particular, the wet etching may be performed using a non-selective wet chemical etch solution. As described, the wet etching may be selective to etch all but the dielectric layer 46 and the masking layer 52, but in principle, it could be that the wet etching is made to have an effective etch rate, i.e. to effectively etch, only with respect to waveguide layers 42a,b and the active layer 18. Other alternatives might exist, according to which, for instance, only the semiconductor material of the substrate 14 is etched, thereby resulting into the protrusion 36 being narrower than the active layer 18 plus sandwiching layers 42a,b. By this measure, the lateral extension 34 of the active layer 18 (as well as of the waveguide layers 42a,b) and the lateral extension 36a of the protrusion 36 of the semiconductor substrate 14 would no longer coincide with each other and may differ.

The wet etching might be isotropic so that, as shown in FIG. 27, the wet etching does not only decreases the width of the protrusion and its upper end formed by active layer 18 and layers 42a,b, but also increases the protrusion's height 36c or, to be more precise, etches into the substrate 14 outside the protrusion 36.

FIG. 2g shows the state during fabrication of device 10 reached by selective growth of a protective layer 62 applied to the state in FIG. 2f. The selectivity is chosen so that the growth of the protective layer 62 does not take place on the dielectric layer 46 and the masking layer 52 or, in different terms, only at the laterally opposite side faces 18a of the active layer 18, portions of the face 24 of the substrate 14 surrounding the protrusion 36 and the side walls of protrusion 36 of the semiconductor substrate 14. The protective layer 62 is, thus, selectively grown to cover the faces 24 of the semiconductor substrate 14 besides the protrusion 36, the side faces 36b of the protrusion 36 of the semiconductor substrate 14 and the side faces 18a of the stack formed by the active layer 18 and its sandwiching layers 42a,b. If it has already not been made obvious from the description so far, it is to be noted that the protective layer 62 abuts the active layer 18 along laterally opposite side faces 18a. That is, in other words, the protective layer 62 is directly in contact with the active layer 18.

The protective layer may be made thin such that, for instance, the protective layer 62 is thinner compared to a height 36c of the protrusion 36 of the semiconductor substrate 14, and/or the protective layer 62 is thinner compared to a thickness 18c of the active layer 18 and/or the protective layer 62 is thinner compared to 100 nm or even 50 nm. Due to the small thickness covering side faces 18a of the active layer 18, a high optical confinement can be achieved, thus resulting in an increase of the modulation bandwidth.

In an exemplary alternative, the lateral extension 36a of the protrusion 36 of the semiconductor substrate 14 may be narrower compared to the lateral extension 34 of the active layer 18. In this case, the protective layer 62 may cover portions of the face 18d of the active layer 18 facing towards the semiconductor substrate 14. In accordance with the described embodiment and the embodiments further described below, the protective layer maybe made of any one of InGaAsP, InP or dielectric material.

FIG. 2h shows the state during fabrication of device 10 reached by the removal of the dielectric layer 46 and the masking layer 52 followed by deposition of a contact metallization element 64 to the state in FIG. 2f. That is, the dielectric layer 46 above the top face 20 of the ridge semiconductor structure 16 and the masking layer 52 covering the overhanging side faces 16b of the ridge semiconductor structure 16 and the face 18b of the upper face of waveguide layer 42a are removed. This is followed by deposition of the contact metallization element 64 wherein the contact metallization element 64 may have a lateral extension 64a equal to or narrower compared to the lateral extension 20b of the top face 20 of the ridge semiconductor structure 16. The removal of the masking layer 52 and the dielectric layer 46 may be performed using wet etching suitable for removing specific dielectric or masking material.

FIG. 2i depicts a state reached from FIG. 2h by depositing a passivation layer 66 on the semiconductor optical device 10 so that the passivation layer 66 covers laterally opposite side faces 64b of the contact metallization element 64, overhanging side walls 16b of the ridge semiconductor structure 16, portions 18b of the upper face of waveguide layer 42a adjacent to the ridge semiconductor structure 16, top face 62a of the portions 62b of the protective layer 62 laterally adjacent to the active layer 18 and portions 62c of the protective layer 62 covering faces 24 of the semiconductor substrate 14, side faces 36b of the protrusions 36 of the semiconductor substrate 14 and side faces 18a of the active layer 18. In other words, the deposition might be selective to lead to a deposition only in areas external to the contact metallization element 64 so that the deposited passivation layer 66 opens on laterally extending faces 64c of the contact metallization element. For example, the passivation layer 66 may be made of a dielectric material. Further, the passivation layer 66 may be made of the same material as the masking layer 52. Furthermore, the passivation layer 66 may partially cover laterally extending faces 64c of the contact metallization element 64.

FIG. 2j shows a state of the semiconductor optical device 10 reached from the state in FIG. 2i by arranging the semiconductor optical device 10 with a contact structure 68. As seen in FIG. 2j, the contact metallization element 64, whose lateral side faces 64b are surrounded by the passivation layer 66, is further structured with a contact structure 68 such that the contact structure 68 is positioned onto the contact metallization element 64 and the contact structure 68 extends laterally from one side 66a of the passivation layer 66 surrounding the ridge semiconductor structure 16 to the other side 66a of the passivation layer 66 surrounding the ridge semiconductor structure 16. It is can be seen from FIG. 2j that the the contact structure 68 extends laterally beyond the ridge semiconductor structure 16 forming an air-bridge contact 68c, wherein the contact structure is supported by a stabilizing structure 70, which is sandwiched between the semiconductor substrate 14 and a part 68b of the contact structure 68.

Further shown in FIG. 2j, the portion 68a of the contact structure 68 extending laterally from one side 66a of the passivation layer 66 to the other side 66a of the passivation layer 66 may extend longitudinally, in a direction parallel to the longitudinal axis 22, along the ridge semiconductor structure 16. The portion 68b of the contact structure 68 which extends laterally beyond the ridge semiconductor structure 16 in the longitudinal plane may be shaped to provide an electrical connection, for instance, as in FIG. 2j, a contact pad 68d. The structuring of the contact structure 68 may be carried out using a deposition process. Further, the contact structure 68 may be made of a metallic material, e.g., Ti, Pt or Au among other metals.

Even further seen in FIG. 2j is the stabilizing structure 70, which is arranged on the top face 24 of the semiconductor substrate 14 so that the portion 68b of the contact structure 68 extending away from the ridge semiconductor structure 16 is supported by the stabilizing structure 70. In other words, the stabilizing structure 70 is sandwiched between the semiconductor substrate 14 and a part of the contact structure 68 forming the contact pad 68d. In particular, the stabilizing structure 70 may be made out of a polymer material such as benzocyclobutene (BCB) or other dielectric materials like e.g., SiNₓ or SiO₂

The state of the device 10, as shown in FIG. 2j, during fabrication may be succeeded by a thinning of the semiconductor substrate 14 from a back side facing away from the ridge structure 16, followed by a deposition of a back contact metallization element 72. The semiconductor substrate 14 of the semiconductor optical device 10 as shown in FIG. 2j might be made thinner by etching and subsequently the back contact metallization element 72 may be deposited on the back face 24a, vertically opposite to face 24, of the semiconductor substrate 14. The contacts 68 and 72 positioned on top of the ridge semiconductor structure 16 and below the semiconductor substrate 14 then provide the semiconductor optical device 10 with an electrical connection. This electrical connection may then be used to electrically activate the semiconductor optical device 10 and thus, allow electrical field injection across the diode 12 of the semiconductor optical device 10.

Thus, FIG. 2a-j described a possible method for fabricating a semiconductor optical device 10, here a DFB laser, and although some possible modification had already been mentioned in describing these figures, further variations are feasible. For example, it is noted that the upper face of the semiconductor optical device 10 may be completely covered by a polymer or the like, subject to planarization of the top side such that planarization results in the upper surface of the thus produced semiconductor optical device 10 becoming flat with the contact element 64 becoming exposed. The contact structure 68 could be left off or might be formed differently. Alternatively, the polymer could be subject to planarization at a state including contact structure 68 so that the contact structure 68 is becomes exposed. No additional supporting structure 70 would be needed as the polymer material BCB might be used.

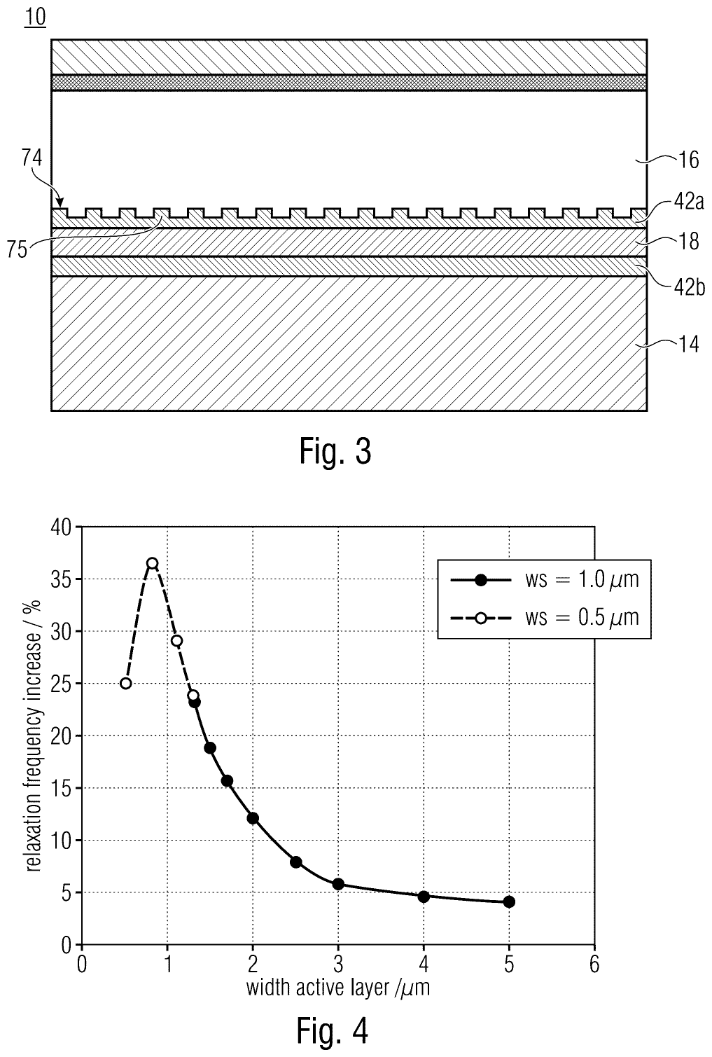

FIG. 3 shows a variation of the semiconductor optical device 10 of FIG. 1, wherein a diffraction grating 74 is etched into the waveguide layer 42a separating the active layer 18 from the ridge semiconductor structure 16. FIG. 3 may, thus, represent an embodiment for an implementation where the semiconductor optical device 10 is embodied as a DFB laser. FIG. 3 shows a sectional view along the longitudinal axis 22 so that the grating 74 is visible. In other words, one of the waveguide layers 42a, 42b, here the upper layer 42a forms a diffraction grating layer 75, wherein the grating 74 is formed on a face of layer 42a facing away from the active layer 18. Additionally, or alternatively, a diffraction grating layer may be etched in the waveguide layer 42b separating the active layer 18 and the semiconductor substrate 14. Alternatively, it is also feasible that the diffraction grating layer is etched through the ridge semiconductor structure 16 or through the semiconductor substrate 14 into the active layer 18. According to an embodiment, the diffraction grating may be a phase shifted index coupling grating or a complex coupling grating. The diffraction gratings may be composed of different parts, which differ, for instance, in an optical characteristic such as a coupling coefficient. In particular, the schematic longitudinal view of a DFB laser in FIG. 3 may form a single-section DFB laser. Moreover, single sections of DFB laser or variations of alternative embodiments of the semiconductor optical device 10 may be used as building blocks to combine and form multiple section device along the longitudinal axis 22.

In the following, various modifications or alternatives of the semiconductor optical device described herein are described by way of multiple examples.

In view of the single-section DFB laser described above and seen in FIG. 3, a multi-section distributed Bragg reflector (DBR) laser may be possible. In such a case, a multi-section DBR laser may comprise one or more of single DBR sections with DBR gratings or one or more of single DBR sections without DBR gratings. For example, a three section DBR laser may comprise an active section, i.e., an active layer sandwiched between two semiconductor structures of opposite conductivity types as described in many embodiments of this invention, a passive section, i.e., an active section wherein the active layer is replaced by a passive waveguide layer, and a passive section wherein the passive section may comprise an implemented DBR grating.

Other examples of the semiconductor optical device integrated with other elements or laser sections include, but are not limited to, the following: electro modulated lasers comprising a DFB-laser section and an electro-absorption modulator (EAM) section; electro modulated lasers with semiconductor optical amplifiers (SOA) comprising a DFB-laser section, an EAM section and an SOA section; passive feedback laser comprising multi-section device such as a DFB-laser and a passive section with a high reflective facet, or a DFB-laser, a facet section and a DBR-section; active feedback layers comprising multi-section devices such as a first DFB-section with a first diffraction grating, an active section and a second DFB-section with a second diffraction grating.

FIG. 4 shows a graph illustrating the variation of the increase in relaxation frequency, in percentage, as a function of the width 34 of the active layer 18, in units of μm, for two different values of the width 50a of the bottom face 50 of the ridge semiconductor structure 16, denoted by ws, namely ws=1.0 μm and ws=0.5 μm for a simulation of an implementation where the semiconductor optical device 10 is embodied as a DFB laser. FIG. 4 shows that a significant increase in relaxation frequency is achieved when the width of the active layer 18 is reduced to be less than 1 μm. As seen in FIG. 4, the relaxation frequency may be increased by approximately 35% when the width 34 of the active layer 18 is reduced to be smaller than 1 μm and the bottom ridge width 50a is 0.5 μm. The reduced width 34 of the active layer 18 and the thin protective layer covering the sides 18a of the active layer 18 of the embodiments of the present invention hence result in a high optical confinement, thereby resulting in a significant increase in relaxation frequency. As described above, for FIG. 4, an n-substrate 14 has been used; wherein, in this case, most of the series resistance stems from the p-Inp ridge 16, in which case the V-shaped or otherwise top-widening ridge 16 helps to reduce the series resistance. However, a p-InP substrate and an n-InP ridge might be used alternatively.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

[1.1] S. Yamaoka et. al. “Uncooled 100-GBaud Operation of Directly Modulated Membrane Lasers on High-Thermal-Conductivity SiC Substrate”, ECOC 2020, paper We1E.3

[1.2] K. Uomi et. al.; Dependence of High-Speed Properties on the Number of Quantum Wells in 1.55μm InGaAs-InGaAsP MQW 1/4 shifted DFB-laser, IEEE Journal of QE, vol. 29, 1993, pp355 . . . 360

[1.3] Yu Han, Qi Tian, Sikang Yang, Jing Luan, Ruigang Zhang, Pengxiang He, Deming Liu, Minming Zhang, “Direct modulation bandwidth enhancement of DFB laser with groove-in-trench waveguide structure,” Proc. SPIE 12154, 13th International Photonics and OptoElectronics Meetings (POEM 2021), 1215401 (20 Jan. 2022); https://doi.org/10.1117/12.2625456

[1.4] K. Suga et. al., “Analysis of TDECQ Dependence on Skew and Extinction Ratio with 106-Gb/s PAM-4 modulation of Directly Modulated Submicron Ridge Localized Buried Heterostructure Lasers”, OFC 2020, paper T3C.2

[1.5] K. Nahakara et. al., “112-Gb/s PAM-4 Uncooled (25° C. to 85° C.) Directly Modulation of 1.3-μm InGaAlAs-MQW DFB BH Lasers with Record High Bandwidth”, ECOC 2020, paper PD2.4

[1.6] U.S. Pat. No. 20,180,090910A

[1.7] U.S. Pat. No. 20,230,106955A

[1.8] M. Aoki et. al. “InP-Based Reversed-Mesa Ridge-Waveguide Structure for High-Performance Long-Wavelength Laser Diodes” IEEE J. of. Quantum electron., vol. 3., 1997, pp672 . . . 683

1. A semiconductor optical device comprising:
a diode formed by
a semiconductor substrate of a first conductivity type;
a ridge semiconductor structure of a second conductivity type, opposite to the first conductivity type, and
an active layer formed between the semiconductor substrate and the ridge semiconductor structure;
wherein the ridge semiconductor structure has a cross-section perpendicular to the active layer which widens from the active layer towards a face of the ridge semiconductor structure facing away from the active layer, and the active layer is laterally confined to be within a projection of the face onto the active layer in a direction perpendicular onto the semiconductor substrate.

2. The semiconductor optical device of claim 1, wherein laterally opposite side faces of the active layer are laterally arranged between opposite sides of the face and sides of an interface between the active layer and the ridge semiconductor structure.

3. The semiconductor optical device of claim 1, wherein the active layer has a width transverse to a longitudinal axis of the ridge semiconductor structure which is less than 1 μm.

4. The semiconductor optical device of claim 1, wherein the ridge semiconductor structure has a trapezoidal cross section.

5. The semiconductor optical device of claim 2, wherein a ratio of the width of the active layer to a width of the face of the ridge semiconductor structure is larger than 7/5.

6. The semiconductor optical device of claim 1, wherein the active layer comprises a multiple quantum well structure, such as made of any one of InGaAsP, InGaAlAs or InGaAsP/InGaAlAs, InGaAsP bulk material, InGaAlAs bulk material, InAs QD layers or InAs QDash layers.

7. The semiconductor optical device of claim 1 wherein the semiconductor substrate comprises a protrusion onto which the active layer is positioned, and whose lateral extension coincides with the active layer.

8. The semiconductor optical device of claim 1 further comprises a protective layer, wherein the protective layer covers laterally opposite side faces of the active layer.

9. The semiconductor optical device of claim 8, wherein the protective layer further covers a face of the semiconductor substrate at portions laterally surrounding the active layer.

10. The semiconductor optical device of claim 8, wherein the semiconductor substrate comprises a protrusion onto which the active layer is positioned, and whose lateral extension coincides with the active layer and wherein the protective layer is thinner compared to one or more of a height of the protrusion of the semiconductor substrate, a thickness of the active layer and 100 nm.

11. The semiconductor optical device of claim 1, wherein the ridge semiconductor structure further comprises a contact structure at the face of the ridge semiconductor structure.

12. The semiconductor optical device of claim 1 further comprises a masking layer, wherein the masking layer covers the semiconductor substrate, the active layer, laterally opposite side-faces of the contact structure and laterally opposite side faces of the ridge semiconductor structure and wherein the active layer is laterally confined to be within a projection of opposite sides of the face of the ridge semiconductor structure covered by the masking layer.

13. The semiconductor optical device of claim 1, wherein material of the ridge semiconductor structure and the semiconductor substrate is indium phosphide.

14. The semiconductor optical device of claim 13 further wherein the material of the ridge semiconductor structure is of p-type indium phosphide.

15. A DFB laser comprising:
a diode formed by
a semiconductor substrate of a first conductivity type;
a ridge semiconductor structure of a second conductivity type, opposite to the first conductivity type, and
an active layer formed between the semiconductor substrate and the ridge semiconductor structure;
wherein the ridge semiconductor structure has a cross-section perpendicular to the active layer which widens from the active layer towards a face of the ridge semiconductor structure facing away from the active layer, and the active layer is laterally confined to be within a projection of the face onto the active layer in a direction perpendicularly onto the semiconductor substrate so that sides of the active layer are laterally arranged between opposite sides of the face and sides of an interface between the active layer and the ridge semiconductor structure;
wherein the active layer comprises a multiple quantum well structure;
wherein the semiconductor substrate comprises a protrusion onto which the active layer is positioned, and whose lateral extension coincides with the active layer; and
wherein the DFB laser further comprises a protective layer covering laterally opposite side faces of the active layer, wherein the protective layer is thinner compared to one or more of
a height of the protrusion of the semiconductor substrate,
a thickness of the active layer, and
100 nm.

16. A fabrication method comprising:
depositing an active layer on top of a semiconductor substrate;
forming a ridge semiconductor structure onto the active layer so that the ridge semiconductor structure widens from the active layer towards a face of the ridge semiconductor structure facing away from the active layer,
performing dry etching using the face of the ridge semiconductor structure as a mask so that the active layer becomes laterally arranged within a projection of the face of the ridge semiconductor structure onto the active layer in a direction perpendicularly onto the semiconductor substrate.

17. The fabrication method of claim 16, further comprising
performing wet etching so as to reduce a lateral width of the active layer relative to the projection of the face of the ridge semiconductor structure onto the active layer.

18. The fabrication method of claim 16, further comprising
performing wet etching so as to reduce a lateral width of the active layer relative to the projection of the face of the ridge semiconductor structure onto the active layer so that sides of the active layer are arranged between opposite sides of the face and sides of an interface between the active layer and the ridge semiconductor structure.

19. The fabrication method of claim 18, wherein the wet etching isotropically etches, in addition to the active layer, the semiconductor substrate so that a protrusion of the semiconductor substrate results onto which the active layer is positioned.

20. The fabrication method of claim 19, further comprising
providing overhanging side faces of the ridge semiconductor structure and a portion of a face of the active layer, which faces the overhanging side faces and is positioned laterally within a projection of the face of the ridge semiconductor structure onto the active layer, with a masking layer, wherein the masking layer is resistive with respect to the wet etching so as to protect the ridge semiconductor structure from getting laterally narrower by the wet etching,
perform the providing with the masking layer by depositing the masking layer using vapor deposition followed by mask-less dielectric-specific dry etching,
performing the dry etching using the face of the ridge semiconductor structure as a mask with the the overhanging side faces of the ridge semiconductor structure and the portion of the face of the active layer, which faces the overhanging side faces and is positioned laterally within a projection of the face of the ridge semiconductor structure onto the active layer, being provided with the masking layer, and
performing the dry etching using the face of the ridge semiconductor structure as a mask so that the dry etching etches beyond the active layer into portions of the semiconductor substrate so that a protrusion of the semiconductor substrate results onto which the active layer is positioned, and whose lateral extension coincides with the active layer.

21. The fabrication method of claim 19, further comprising
performing the wet etching so as to reduce the lateral extension of the protrusion of the semiconductor substrate so that sides of the protrusion of the semiconductor substrate are arranged between opposite sides of the face of the ridge semiconductor structure and sides of the interface between the active layer and the ridge semiconductor structure.
